(19) United States
(12) Patent Application Publication
(10) Pub. No.: US 2016/0091532 A1
(43) Pub. Date: Mar. 31, 2016

(54) FLEXIBLE FILM ELECTRICAL-TEST SUBSTRATES WITH CONDUCTIVE COUPLING POST(S) FOR INTEGRATED CIRCUIT (IC) BUMP(S) ELECTRICAL TESTING, AND RELATED METHODS AND TESTING APPARATUSES

(71) Applicant: QUALCOMM Incorporated, San Diego, CA (US)

(72) Inventors: Young Kyu Song, San Diego, CA (US); Hong Bok We, San Diego, CA (US); Dong Wook Kim, San Diego, CA (US); Chin-Kwan Kim, San Diego, CA (US); Jae Sik Lee, San Diego, CA (US); Kyu-Pyung Hwang, San Diego, CA (US); Seung Hyuk Kang, San Diego, CA (US)

(21) Appl. No.: 14/498,291

(22) Filed: Sep. 26, 2014

(51) Int. Cl. G01R 1/073; H01L 21/66; H01L 21/48; G01R 31/28

(52) U.S. Cl. CPC G01R 1/0735; G01R 31/2887; H01L 22/30; H01L 21/4853; H01L 21/4857

(57) ABSTRACT

Flexible film electrical-test substrates with at least one conductive contact post for integrated circuit (IC) bump(s) electrical testing, and related methods and testing apparatuses are disclosed. The backside structure of an electrical-test substrate comprises a flexible dielectric film structure. One or more fine-pitched conductive coupling posts are formed on conductive pads disposed on a front side of the flexible dielectric film structure through a fabrication process. A first pitch of the conductive coupling post(s) in the flexible dielectric film structure is provided to be the same or substantially the same as a second pitch of one or more bumps in an IC, such as die or interposer (e.g., forty (40) micrometers (μm) or less). This allows the conductive coupling post(s) to be placed into mechanical contact with at least one bump of the IC, point-by-point, during an electrical test to electrically testing of the IC.

### BACKGROUND

I. Field of the Disclosure

The technology of the disclosure relates generally to electrical testing of die to be provided in multi-chip modules (MCMs).

II. Background

Computing devices have become commonplace throughout society. The increasing presence of such computing devices has accelerated in part because of the increasing functionality and versatility of such computing devices. This increase in functionality and versatility has been enabled by providing increasingly powerful processing capabilities in small packages as loosely recognized by Moore's Law. As a result, companies have been trying to increase functional integration more quickly than Moore's Law or circuit performance requirements. However, pressures to increase processing capabilities while decreasing the size of integrated circuits (ICs) have strained conventional manufacturing processes, especially as the node size within ICs has been reduced to low nanometer (nm) dimensions (e.g., <20 nm). Thus, there has been a proliferation of interconnect schemes such as silicon in package, package-on-package, and system-in-a-package (SiP) multi-chip modules (MCMs) schemes to decrease the size of ICs.

One example of a MCM is a 2.5 dimension (2.5D) IC system. FIG. 1 illustrates an example of a 2.5D IC system 10. As illustrated in FIG. 1, the 2.5D IC system 10 is provided in a form of a SiP MCM that has two dies 12(1), 12(2) (dice 12(1), 12(2)) mounted in a single package 14 in a single plane. A silicon interposer 16 is placed between a SiP substrate 18 and the two die 12(1), 12(2). The silicon interposer 16 has through-silicon vias (TSVs) 20 connecting the metallization layers of the dice 12(1) 12(2). The dice 12(1), 12(2) are attached to the silicon interposer 16 using micro-bumps 22(1), 22(2), which are approximately ten (10) micrometers (μm) in diameter. The silicon interposer 16 is attached to the SiP substrate 18 using regular flip-chip bumps 24, which are typically one hundred (100) μm in diameter. The single package 14 is interconnected to a circuit board 26 through package bumps 28. One advantage of the 2.5D IC system 10 is that it is an incremental step from a traditional 2D IC/SiP technology that offers tremendous increases in capacity and performance. There are also yield advantages, because it's easier to make a number of small dice, as opposed to a single, large die.

It may be desired to reduce the pitch between the micro-bumps 22(1), 22(2) of the dice 12(1), 12(2) in the 2.5D IC system 10 in FIG. 1. This would allow for a greater number of interconnections to and between the dies 12(1), 12(2) without having to increase the size of the dice 12(1), 12(2) or the silicon interposer 16. In this regard, FIG. 2 illustrates a bottom view of the dice 12(1), 12(2) in the 2.5D IC system 10 in FIG. 1. Subsets rows 30(1), 30(2) of the micro-bumps 22(1), 22(2) are shown disposed on bottoms 32(1), 32(2) of the respective dice 12(1), 12(2) that are interconnected by a micro via structure 34 in the silicon interposer 16 (not shown in FIG. 2). In this example, the ten (10) rows of micro-bumps 22(1), 22(2) in the subset rows 30(1), 30(2) are provided with a forty (40) μm pitch bump with a 2/2 μm line/space (L/S) die split architecture. This die split architecture allows for ten (10) micro-bumps 22(1), 22(2) in each row to be interconnected with the micro via structure 34.

It may be desired to check the electrical integrity of the dice 12(1), 12(2) in FIG. 2 before being packaged in the 2.5D IC system 10. In this manner, if there is a fault in a die 12(1), 12(2), the faulty die 12(1), 12(2) can be discarded and replaced prior to forming the 2.5D IC system 10. To check the electrical integrity of the dice 12(1), 12(2) in the 2.5D IC system 10 in FIGS. 1 and 2, electrical test equipment can be provided to establish mechanical contacts with the micro-bumps 22(1), 22(2) to provide bump probing. However as an example, plan of record (POR) electrical test jigs used to electrically test the dies 12(1), 12(2) may only be capable to mechanically contact micro-bumps 22(1), 22(2) down to a sixty (60) μm micro-bump pitch due to the difficulty in make mechanical contacts in a small pitch, or due to pitch constraints. However, as discussed above, it may be desired to provide a micro-bump pitch in a die of forty (40) μm or less. A probe card, such as needle type, vertical type, and micro electro-mechanical system (MEMS) type, can be used to perform electrical testing of dice. However, it may be difficult or expensive to form probe cards and new probe test equipment with fine-pitched contact elements for bringing fine-pitched micro-bumps on a die into contact, rather than using less expensive electrical test jig equipment.

Thus, there is a need to facilitate mechanical contact electrical testing of die with fine-pitched micro-bumps, such as forty (40) μm or less, to be able to provide for a larger number of interconnections in a MCM without increasing package size.

### SUMMARY OF THE DISCLOSURE

Aspects disclosed in the detailed description include flexible film electrical-test substrates with at least one conductive coupling post for integrated circuit (IC) bump(s) electrical testing. Related methods and testing apparatuses are also disclosed. The backside structure of an electrical-test substrate comprises a flexible dielectric film structure. One or more fine-pitched conductive coupling posts are formed on conductive pads disposed on a front side of the flexible dielectric film structure through a fabrication process. A first pitch of the conductive coupling post(s) in the flexible dielectric film structure is provided to be the same or substantially the same as a second pitch of one or more bumps in an integrated circuit (IC), such as a semiconductor die or interposer (e.g., 40 micrometers μm or less). This allows the conductive coupling post(s) to be coupled to or placed into mechanical contact with at least one bump of the IC, point-by-point, during an electrical test to perform electrical testing of the IC. The electrical-test substrate also includes connection areas that are connected within the electrical-test substrate to respective conductive coupling post(s) to allow for an electrical-test machine to electrically couple with the bump(s) coupled by the conductive coupling post(s) during the electrical test.

Providing the backside structure of the electrical-test substrate as the flexible dielectric film structure can provide several non-limiting benefits. For example, providing the flexible dielectric film structure in the electrical-test substrate allows the electrical-test substrate to be dispensed as a consumable (e.g., from a reel) in an electrical test probe system. This can allow the electrical-test substrate to be easily replaced in an automated manner with another electrical-test substrate when the conductive contacts post(s) is damaged from coupling, such as through mechanical contact, with at least one bump in an IC after repeated use in testing. Further, as another example, providing the backside structure comprised of the flexible dielectric film structure allows a test probe to apply force to the backside of the flexible dielectric film structure as a protective material, without contacting the conductive coupling post(s), when bringing the conductive coupling post(s) into coupling with or in contact with bump(s) of an IC during electrical testing. Thus, the test probe can contact the flexible dielectric film structure to control the vertical displacement of the conductive coupling post(s) brought into coupling to or mechanical contact with the bump(s), to minimize damage of the conductive coupling post(s) during electrical testing for longer use of the electrical-test substrate.

In this regard in one aspect, an electrical-test substrate is provided. The electrical-test substrate is used for providing electrical contact to bumps in an IC during electrical testing of the IC. The electrical-test substrate comprises a backside structure comprising a flexible dielectric film structure. The electrical-test substrate further comprises at least one conductive pad formed over a front side of the flexible dielectric film structure. The electrical-test substrate further comprises at least one opening formed over of the at least one conductive pad at a first pitch. The electrical-test substrate further comprises at least one conductive coupling post positioned within the at least one opening to provide a second pitch of the at least one conductive coupling post at substantially the first pitch. The at least one conductive coupling post is configured for coupling with at least one bump of an IC during electrical testing of the IC.

In another aspect, a method of fabricating an electrical-test substrate comprising a plurality of conductive coupling posts configured for coupling to at least one bump in an IC during electrical testing of the IC is provided. The method comprises providing a backside structure comprised of a flexible dielectric film structure having a back side and a front side. The method also comprises forming a conductive layer overlying the front side of the flexible dielectric film structure. The method also comprises forming a first at least one opening in the conductive layer to provide remaining portions of the conductive layer. The method also comprises forming a solder resist layer in the first at least one opening to form a second at least one opening of a first depth and having a first pitch, over the remaining portions of the conductive layer. The method also comprises forming at least one conductive coupling post in the second at least one opening to provide a second pitch of the at least one conductive coupling post at substantially the first pitch.

In another aspect, an electrical test probe for electrical testing of an IC is provided. The electrical test probe comprises an unwind reel configured to be rotated in a first direction in response to a rotation signal. The electrical test probe also comprises a wind reel configured to be rotated in the first direction in response to the rotation signal. The electrical test probe also comprises a tape comprising a plurality of electrical-test substrates disposed end-to-end from a first end of the tape to a second end of the tape, the first end of the tape wound around the unwind reel and the second end of the tape wound around the wind reel. Each of the plurality of electrical-test substrates comprises a backside structure comprising a flexible dielectric film structure. Each of the plurality of electrical-test substrates also comprises at least one conductive pad formed over a front side of the flexible dielectric film structure. Each of the plurality of electrical-test substrates also comprises at least one opening formed over the at least one conductive pad at a first pitch. Each of the plurality of electrical-test substrates also comprises at least one conductive coupling post positioned within the at least one opening to provide a second pitch of the at least one conductive coupling post at substantially the first pitch of the at least one opening, the at least one conductive coupling post configured for coupling with at least one bump of an IC during electrical testing of the IC.

The electrical test probe also comprises a test press disposed between the unwind reel and the wind reel. The test press is configured to be disposed downward in response to a test signal to come into contact with the backside structure of an electrical-test substrate among the plurality of electrical-test substrates unwound from the unwind reel and disposed below the test press to press the at least one conductive coupling post in the electrical-test substrate to couple with the at least one bump in the IC disposed underneath the test press. The electrical test probe also comprises a controller. The controller is configured to generate the rotation signal to cause the unwind reel and the wind reel to rotate in the first direction to dispose an unwound electrical-test substrate among the plurality of electrical-test substrates below the test press. The controller is also configured to generate the test signal to cause the test press to be disposed downward to come into contact with the backside structure of the electrical-test substrate among the plurality of electrical-test substrates unwound from the unwind reel to press the at least one conductive coupling post in the electrical-test substrate to couple with the at least one bump in the IC disposed underneath the test press.

### BRIEF DESCRIPTION OF THE FIGURES

FIG. 1 is a cross-sectional view of an exemplary 2.5 dimension (2.5D) integrated circuit (IC) system illustrating micro-bumps of two adjacent dies interconnected by through-silicon vias (TSVs) of a silicon interposer;

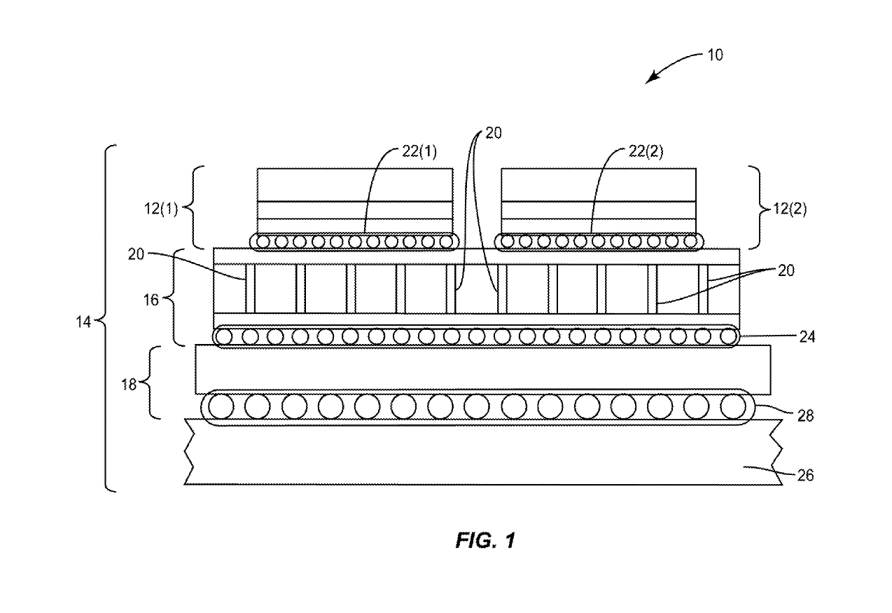

FIG. 2 is a bottom view of the 2.5D IC in FIG. 1 illustrating fine-pitch dice micro-bumps interconnected to a micro via structure of the silicon interposer to interconnected the dice to the silicon interposer;

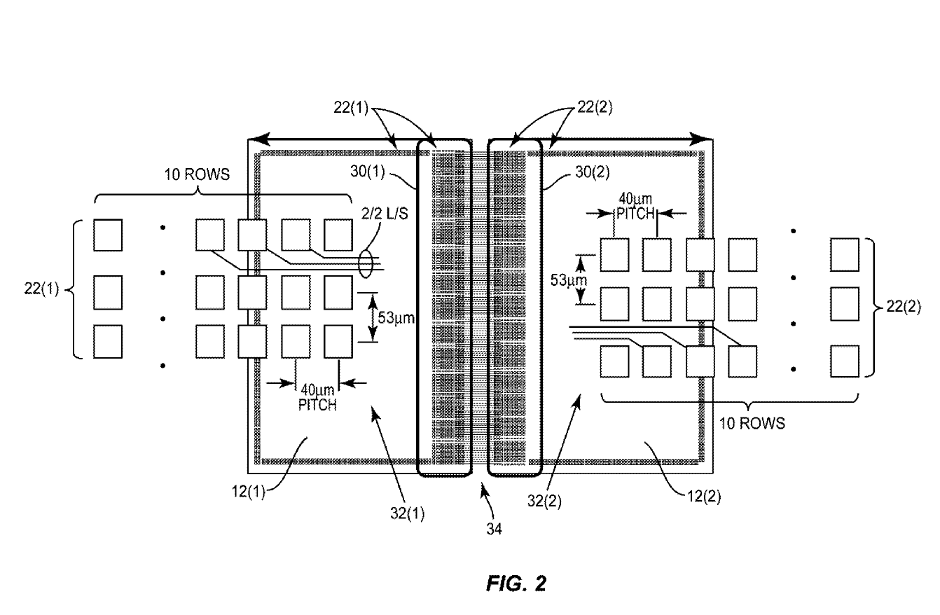

FIG. 3 is a cross-sectional view of an exemplary flexible film electrical-test substrate disposed above fine-pitch bumps of an IC, wherein the flexible film electrical-test substrate has a backside structure comprising a flexible dielectric film structure and conductive coupling posts for coupling with at least one fine-pitch bump in the IC during electrical testing of the IC;

FIG. 4 is another cross-sectional view of another flexible film electrical-test substrate having a backside structure comprising a flexible dielectric film structure and conductive coupling posts for coupling to at least one fine-pitch bump in the IC;

FIG. 5 is an electrical test probe for electrical testing of an IC, wherein the electrical test probe is configured to dispense the flexible film electrical-test substrate in FIG. 3 from a tape of electrical-test substrates above bumps in an IC, and press conductive coupling posts to couple with one or more bumps in the IC to electrically test the IC;

FIG. 6 illustrates an exemplary process of fabricating the flexible film electrical-test substrate in FIG. 4; and

FIG. 7 is a schematic diagram of a generalized representation of an exemplary controller that can be included in the electrical test probe in FIG. 5, wherein an exemplary computer system is adapted to execute instructions from an exemplary computer readable medium to control disposing of conductive coupling posts of an electrical-test substrate to couple with one or more bumps in an IC to electrically test the IC.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include flexible film electrical-test substrates with at least one conductive coupling post for integrated circuit (IC) bump(s) electrical testing. Related methods and testing apparatuses are also disclosed. The backside structure of an electrical-test substrate comprises a flexible dielectric film structure. One or more fine-pitched conductive coupling posts are formed on conductive pads disposed on a front side of the flexible dielectric film structure through a fabrication process. A first pitch of the conductive coupling post(s) in the flexible dielectric film structure is provided to be the same or substantially the same as the pitch of one or more bumps in an integrated circuit (IC), such as a semiconductor die or interposer (e.g., 40 micrometers μm or less). This allows the conductive coupling post(s) to be coupled to or placed into mechanical contact with at least one bump of the IC, point-by-point, during an electrical test to perform electrical testing of the IC. The electrical-test substrate also includes connection areas that are connected within the electrical-test substrate to respective conductive coupling post(s) to allow for an electrical-test machine to electrically couple with the bump(s) coupled by the conductive coupling post(s) during the electrical test.

Providing the backside structure of the electrical-test substrate as the flexible dielectric film structure can provide several non-limiting benefits. For example, providing the flexible dielectric film structure in the electrical-test substrate allows the electrical-test substrate to be dispensed as a consumable (e.g., from a reel) in an electrical test probe system. This can allow the electrical-test substrate to be easily replaced in an automated manner with another electrical-test substrate when the conductive contacts post(s) is damaged from coupling, such as through mechanical contact, with at least one bump in an IC after repeated use in testing. Further, as another example, providing the backside structure comprised of the flexible dielectric film structure allows a test probe to apply force to the backside of the flexible dielectric film structure as a protective material, without contacting the conductive coupling post(s), when bringing the conductive coupling post(s) into coupling with or in contact with bump(s) of an IC during electrical testing. Thus, the test probe can contact the flexible dielectric film structure to control the vertical displacement of the conductive coupling post(s) brought into coupling to or mechanical contact with the bump(s), to minimize damage of the conductive coupling post(s) during electrical testing for longer use of the electrical-test substrate.

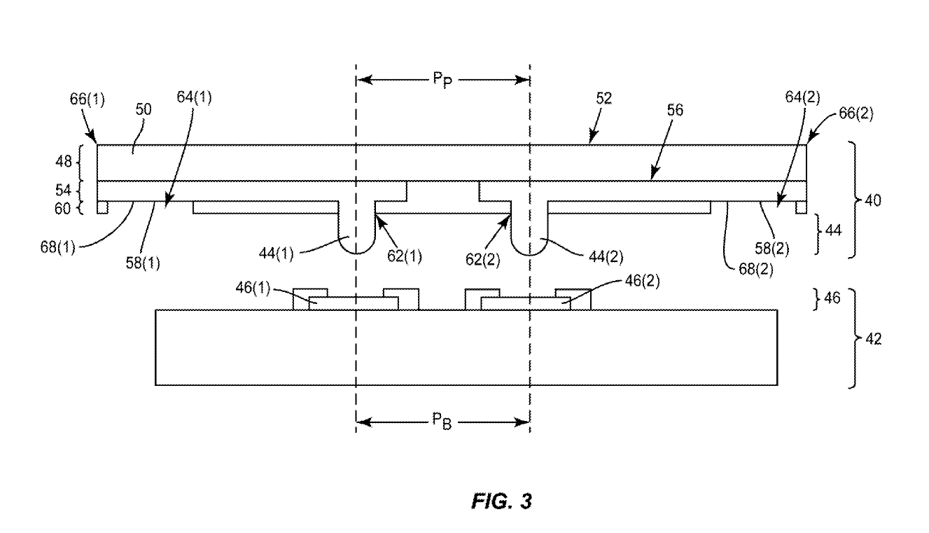

In this regard, FIG. 3 is a cross-sectional view of an exemplary electrical-test substrate 40. As discussed in more detail below, the electrical-test substrate 40 is configured to be employed in an electrical test probe to electrically test an IC 42. As non-limiting examples, the IC 42 to be electrically tested can be a semiconductor die for a semiconductor package (e.g., a semiconductor die for a 2DIC, 2.5DIC, or 3DIC semiconductor package) or an interposer. It may be desired to electrically test the IC 42 before being packaged in a semiconductor package or chip so that the IC 42 is not used in the package or chip if determined to be faulty. In this manner, the electrical-test substrate 40 has one or more conductive coupling posts 44 that have the same or substantially the same pitch P_{P} as the pitch P_{B} of one or more interconnect bumps 46 exposed from the IC 42 that provide interconnects to the IC 42. The interconnect bumps 46 may also be known or referred to as “micro-bumps.” In this manner, the one or more conductive coupling posts 44 can be brought into mechanical contact with the one or more interconnect bumps 46 to allow an electrical test probe to provide signals to the one or more interconnect bumps 46 through the one or more conductive coupling posts 44 to electrically test the IC 42.

Because the IC 42 may have hundreds if not thousands of interconnect bumps 46, the electrical test probe can reuse the electrical-test substrate 40 for the conductive coupling posts 44 to be coupled with one or more of the interconnect bumps 46 desired as part of electrically testing the IC 42. This is opposed to testing the IC 42 as part of a larger semiconductor package or chip where it may not be possible to test lower resolution functions of the IC 42. For example, if the conductive coupling posts 44 are provided as conductive contact posts, the conductive contact posts can be brought into mechanical contact with any number of the interconnect bumps 46 desired as part of electrically testing the IC 42.

With continuing reference to FIG. 3, only two (2) interconnect bumps 46(1), 46(2) on the IC 42 are shown, but it should be noted that hundreds if not thousands of interconnect bumps 46 may be provided in the IC 42. The pitch P_{B} of the interconnect bumps 46(1), 46(2) in the IC 42 is approximately forty (40) micrometers (μm) in this example to provide finer-pitch interconnect bumps 46 in the IC 42. Providing the fine-pitch interconnect bumps 46 in the IC 42 allows a higher density of interconnect bumps 46 to be provided in the IC 42 for a given size of the IC 42. As the node size within ICs, such as the IC 42, has been reduced to low nanometer (nm) dimensions (e.g., <20 nm), providing fine-pitch interconnections may avoid having to increase the IC 42 even though a greater number of nodes are provided in the IC 42. In this regard, to allow for the electrical-test substrate 40 to make electrical contact with the fine-pitch interconnect bumps 46(1), 46(2) in the IC 42, the two (2) conductive coupling posts 44(1), 44(2) are provided in the electrical-test substrate 40. However, the electrical-test substrate 40 is not limited to two (2) conductive coupling posts 44(1), 44(2). For example, it may be desired to form more than two (2) conductive coupling posts 44 to probe more than two (2) interconnect bumps 46(1), 46(2) in the IC 42 at the same time. Also as an example, the conductive coupling posts 44(1), 44(2) may be formed from a copper material, or any other type of conductive material desired, including but not limited to nickel, cobalt, gold, silver, aluminum, platinum, or alloys thereof. The pitch P_{P} of the conductive coupling posts 44(1), 44(2) in the electrical-test substrate 40 is also approximately forty (40) micrometers (μm) in this example to match the pitch P_{B} of the interconnect bumps 46(1), 46(2) in the IC 42. In this manner, a conventional electrical test probe, such as an electrical test jig, can be used to electrically test the IC 42, because the conductive coupling posts 44(1), 44(2) of the electrical-test substrate 40 can be brought into mechanical contact with the fine-pitch interconnect bumps 46(1), 46(2).

Note that the pitch P_{P} of the conductive coupling posts 44(1), 44(2) in the electrical-test substrate 40 can be provided to be lower than forty (40) μm to match a pitch P_{B} of the interconnect bumps 46(1), 46(2) in the IC 42 provided as lower than forty (40) μm. For example, the pitch P_{B} of the interconnect bumps 46(1), 46(2) in the IC 42 may be thirty (30) μm or twenty (20) μm as non-limiting examples. Also, as another non-limiting example, the conductive coupling posts 44(1), 44(2) may be approximately 15 μm in diameter or less.

With continuing reference to FIG. 3, to provide for the fine-pitch conductive coupling posts 44(1), 44(2) in the electrical-test substrate 40, a backside structure 48 is provided. The backside structure 48 in this example is comprised of a flexible dielectric film structure 50 provided in the electrical-test substrate 40 to provide an electrical-test substrate as a single layer. In one exemplary aspect, the backside structure 48 can be comprised of the flexible dielectric film structure 50 provided in the electrical-test substrate 40. This example is opposed to a dielectric structure with conductive wire structures disposed thereon that is folded up into a lump structure to provide exposed electrical contact pads on each side of the conductive wire structures. By providing the flexible dielectric film structure 50 as a flexible structure, the electrical-test substrate 40 can be provided in the electrical test probe as a consumable. A plurality of the electrical-test substrates 40 can be provided on a tape and unwound from a reel to be disposed over the IC 42 to be electrically tested. Thus, when the conductive coupling posts 44(1), 44(2) are damaged or impacted such that they no longer make sufficient mechanical contact with interconnect bumps of an IC, the electrical test substrate 40 can be replaced with another one in an automated manner. Further, by providing the backside structure 48 of the electrical-test substrate 40 comprised of the flexible dielectric film structure 50 allows a test probe to apply force to a back side 52 of the flexible dielectric film structure 50 as a protective material, without contacting and potentially damaging the conductive coupling posts 44(1), 44(2).

With continuing reference to FIG. 3, the flexible dielectric film structure 50 facilitates the forming of an additional conductive layer 54 of an electrical interconnect in the electrical-test substrate 40. For example, the flexible dielectric film structure 50 may be a polymer, including but not limited to polyimide (PI), polydimethylsiloxane (PDMS), and polyethylene terephalate (PET), or combinations or derivatives thereof. Polyimide may be a particularly useful material to provide the flexible dielectric film structure 50. Polyimide has characteristics of thermal stability at higher temperatures (e.g., up to 350° Celsius (C)) to facilitate fabrication processes. Polyimide has good adhesion characteristics to conductive and other under bump metallurgy (UBM) materials that are to be provided in the electrical-test substrate 40 to facilitate the forming of the fine-pitch conductive coupling posts 44(1), 44(2), as will be discussed below. Polyimide also has low shrinkage characteristics on curing. However, note that the electrical-test substrate 40 is not limited to a polymer or polyimide material.

With continuing reference to FIG. 3, as discussed above, the flexible dielectric film structure 50 facilitates the forming of the additional conductive layer 54 of an electrical interconnect in the electrical-test substrate 40. The conductive layer 54 is disposed on a front side 56 of the flexible dielectric film structure 50. The conductive layer 54 facilitates electrical connections to be provided in the electrical-test substrate 40 between an electrical test probe and the conductive coupling posts 44(1), 44(2) for electrical testing. As will be discussed in more detail below, processes can be performed during fabrication of the electrical-test substrate 40 to remove portions of the conductive layer 54 to provide for two residual (2) conductive pads 58(1), 58(2) to provide separate electrical connectivity to the two (2) conductive coupling posts 44(1), 44(2) to avoid shorting of the conductive coupling posts 44(1), 44(2). In this example, to provide for the fine-pitch conductive coupling posts 44(1), 44(2) in the electrical-test substrate 40, a solder resist layer 60 is disposed on the conductive layer 54. Openings 62(1), 62(2) are formed in the solder resist layer 60 above the conductive pads 58(1), 58(2) as part of fabrication processes to allow the conductive coupling posts 44(1), 44(2) to be formed therein. Because the openings 62(1), 62(2) are formed over the conductive pads 58(1), 58(2) with the desired pitch P_{P} of the bump pitch P_{B}, the conductive coupling posts 44(1), 44(2) can be formed in the openings 62(1), 62(2) to provide the conductive coupling posts 44(1), 44(2) of the bump pitch P_{B} as well as for making mechanical contact with the interconnect bumps 46(1), 46(2) of the IC 42 during electrical testing. The conductive coupling posts 44(1), 44(2) are formed as protruding rounded structures when formed in the openings 62(1), 62(2) as part of a fabrication process in this example. However, other shapes are possible.

Also with continuing reference to FIG. 3, to provide for an electrical test probe to make electrical contact to the conductive coupling posts 44(1), 44(2) when using an installed electrical-test substrate 40 for testing, additional openings 64(1), 64(2) are formed in the solder resist layer 60 at ends 66(1), 66(2) of the electrical-test substrate 40. This exposes conductive end pads 68(1), 68(2) of the conductive pads 58(1), 58(2) to allow for an electrical test probe to electrically contact the exposed conductive end pads 68(1), 68(2) to electrically connect to the conductive coupling posts 44(1), 44(2).

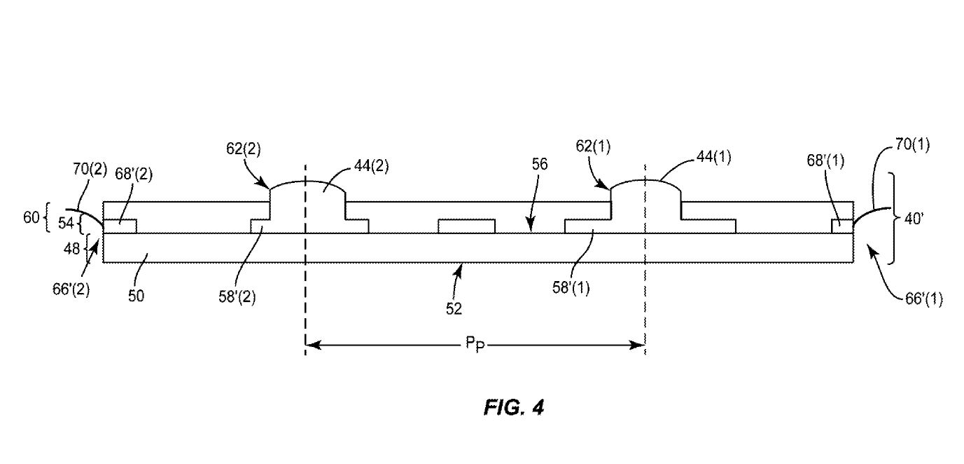

FIG. 4 illustrates an alternative cross-sectional view of an electrical-test substrate 40′ that is similar to the electrical-test substrate 40 in FIG. 3. The electrical-test substrate 40′ in FIG. 4 is illustrated in an orientation with the flexible dielectric film structure 50 disposed below the conductive coupling posts 44(1), 44(2). Common elements between the electrical-test substrate 40 in FIG. 3 and the electrical-test substrate 40′ in FIG. 4 are shown with common element numbers, and thus will not be re-described for the electrical-test substrate 40′. However, in the electrical-test substrate 40′ in FIG. 4, openings 62(1), 62(2) are not provided in the solder resist layer 60 to conductive pads 58′(1), 58(′2) for providing separate electrical connectivity to the two (2) conductive coupling posts 44(1), 44(2). In this example, exposed conductive end pads 68′(1), 68′(2) are formed from separate residual portions of the conductive layer 54 that are not exposed through the solder resist layer 60, but rather at the ends 66′(1), 66′(2) of the electrical-test substrate 40′ to facilitate an electrical connection to the conductive coupling posts 44(1), 44(2) through conductive wires 70(1), 70(2) connected to the exposed conductive end pads 68′(1), 68′(2).

As discussed above, the electrical-test substrates 40, 40′ in FIGS. 3 and 4 can be provided in an electrical test probe to facilitate electrical testing of the IC 42 with fine-pitch interconnect bumps 46(1), 46(2). By providing the backside structure 48 of the electrical-test substrates 40, 40′ as the flexible dielectric film structure 50, the electrical-test substrates 40, 40′ can be dispensed as a consumable (e.g., from a reel) in an electrical test probe system. This can allow the electrical-test substrates 40, 40′ to easily be replaced in an automated manner with another electrical-test substrate when the conductive coupling posts 44(1), 44(2) are damaged from mechanical contact with the interconnect bumps 46(1), 46(2) of the IC 42 after repeated use in testing.

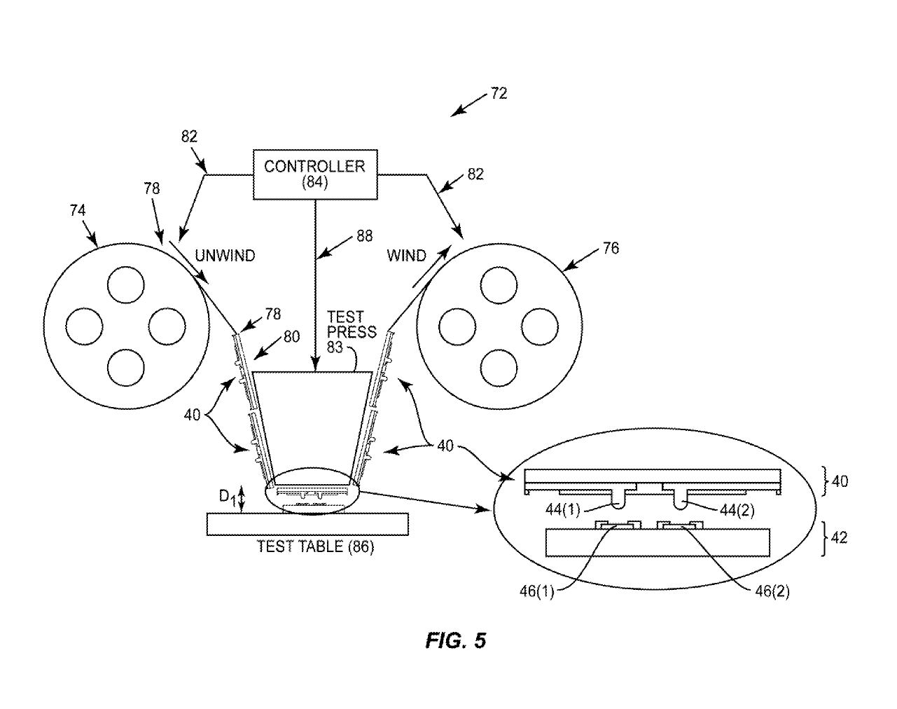

In this regard, FIG. 5 illustrates an electrical test probe 72 configured to use an electrical-test substrate having a backside structure comprised of a flexible dielectric film structure to electrically test an IC. In this example, the electrical-test substrate 40 in FIG. 3 is shown as being used by the electrical test probe 72 to electrically test the IC 42 described with regard to FIG. 3. As shown in FIG. 5, the electrical test probe 72 comprises an unwind reel 74 and a wind reel 76. A tape 78 of the electrical-test substrate 40 that is aligned linearly end-to-end is provided that is wound around the unwind reel 74. A portion 80 of the tape 78 is unwound from the unwind reel 74 and disposed below a test press 83 and wound on the wind reel 76. The unwind reel 74 and the wind reel 76 are both configured to be rotated in a clockwise direction in response to receipt of a rotation signal 82 from a controller 84. Thus, when it is desired to dispose a next electrical-test substrate 40 on the tape 78 below the test press 83 to be used for electrically testing the IC 42, the controller 84 can generate the rotation signal 82 to cause the unwind reel 74 and the wind reel 76 to rotate in the clockwise direction. For example, each electrical-test substrate 40 may have a set number of times that it is used before the conductive coupling posts 44(1), 44(2) are deemed to be damaged and thus unfit for further use. In this instance, by the electrical-test substrate 40 being provided with the flexible dielectric film structure 50, another electrical-test substrate 40 can simply be unwound and disposed underneath the test press 83 with the consumed electrical-test substrate 40 rotated to eventually be wound on the wind reel 76.

As discussed above, the test press 83 is provided as part of the electrical test probe 72 in FIG. 5. The test press 83 is disposed between the unwind reel 74 and the wind reel 76. The test press 83 is configured to be disposed downward towards the IC 42 on a test table 86 in response to a test signal 88 generated by the controller 84. This causes the test press 83 to come into contact with the backside structure 48 of the electrical-test substrate 40 on the tape 78 disposed below the test press 83 to press the conductive coupling posts 44(1), 44(2) in the electrical-test substrate 40 into mechanical contact with the interconnect bumps 46(1), 46(2) in the IC 42. The IC 42 can be translated on the test table 86 to align different interconnect bumps 46 therein with the conductive coupling posts 44(1), 44(2) to probe different interconnect bumps 46 in the IC 42. The controller 84 can also control the distance to which the test press 83 is disposed downward against the backside structure 48 of the electrical-test substrate 40 to control the vertical displacement travel distance D₁ of the conductive coupling posts 44(1), 44(2). In this manner, the controller 84 can control the mechanical contact of the conductive coupling posts 44(1), 44(2) with the interconnect bumps 46(1), 46(2) of the IC 42, so as to minimize damage to the conductive coupling posts 44(1), 44(2) as an example.

As a non-limiting example, by providing the backside structure 48 of the electrical-test substrate 40 comprised of the flexible dielectric film structure 50, the test press 83 of the electrical test probe 72 in FIG. 5 is able to apply a force to the backside structure 48 as a protective material of the electrical-test substrate 40. The test press 83 does not have to contact the conductive coupling posts 44(1), 44(2) to bring the conductive coupling posts 44(1), 44(2) in contact with the interconnect bumps 46(1), 46(2) of the IC 42 during electrical testing of the IC 42. Thus, the electrical test probe 72 can contact the backside structure 48 of the electrical-test substrate 40 to control the vertical displacement of the conductive coupling posts 44(1), 44(2) brought into mechanical contact with the interconnect bumps 46(1), 46(2) of the IC 42, to minimize damage of the conductive coupling posts 44(1), 44(2) during electrical testing for longer use of the electrical-test substrate 40.

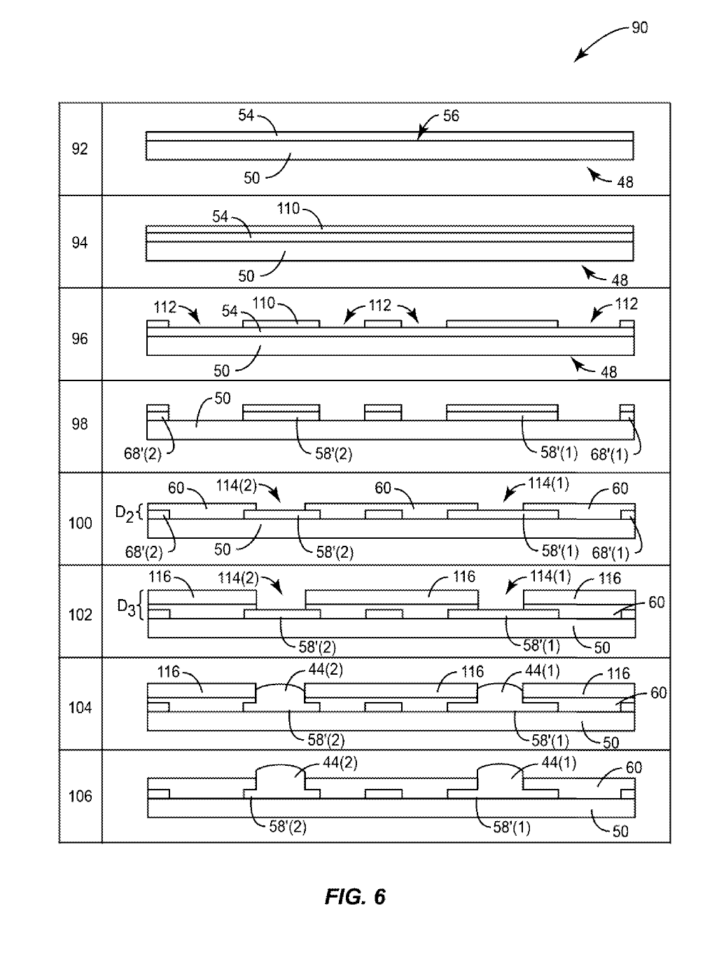

FIG. 6 illustrates an exemplary process 90 that can be employed to fabricate the electrical-test substrate 40 in FIG. 4. In this regard, the backside structure 48 comprised of the flexible dielectric film structure 50 is provided (block 92). The flexible dielectric film structure 50 may be provided in cut portions or in a continuous film. The conductive layer 54 is formed over the front side 56 of the flexible dielectric film structure 50 (block 92). The conductive layer 54 may be laminated or sputtered onto the flexible dielectric film structure 50 as non-limiting examples. Then, a first photoresist layer 110 is formed over the conductive layer 54 (block 94). The first photoresist layer 110 is provided to be able to expose and develop a first plurality of openings 112 in the conductive layer 54 and to provide locations for further etching or stripping of the conductive layer 54 down to the flexible dielectric film structure 50 (block 96). This additional etching or stripping of the conductive layer 54 in the first plurality of openings 112 is to form the conductive pads 58′(1), 58(′2) and the exposed conductive end pads 68′(1), 68′(2) of FIG. 4 from the remaining, non-etched or non-stripped portions of the conductive layer 54 (block 98).

With continuing reference to FIG. 6, after the remaining first photoresist layer 110 is removed, a solder resist layer 60 is disposed in the first plurality of openings 112 (block 100). Portions of the solder resist layer 60 disposed over the conductive pads 58′(1), 58′(2) are removed to form a second plurality of openings 114(1), 114(2) of a first depth D₂ and having a pitch of forty (40) μm or less over remaining portions of the conductive pads 58′(1), 58′(2). The second plurality of openings 114(1), 114(2) will provide for locations where the conductive coupling posts 44(1), 44(2) can be formed, also at the pitch of forty (40) μm or less, since the second plurality of openings 114(1), 114(2) has a pitch of forty (40) μm or less. Thereafter, a second photoresist layer 116 is disposed over the remaining solder resist layer 60 to increase the depth of the second plurality of openings 114(1), 114(2) to a second depth D₃ (block 102). Thereafter, the conductive coupling posts 44(1), 44(2) are formed in the second plurality of openings 114(1), 114(2) such that the pitch of the conductive coupling posts 44(1), 44(2) is forty (40) μm or less (block 104). The conductive coupling posts 44(1), 44(2) may be formed by a post-plating process as an example. Thereafter, the second photoresist layer 116 can be removed to further expose the conductive coupling posts 44(1), 44(1) from the solder resist layer 60 (block 106).

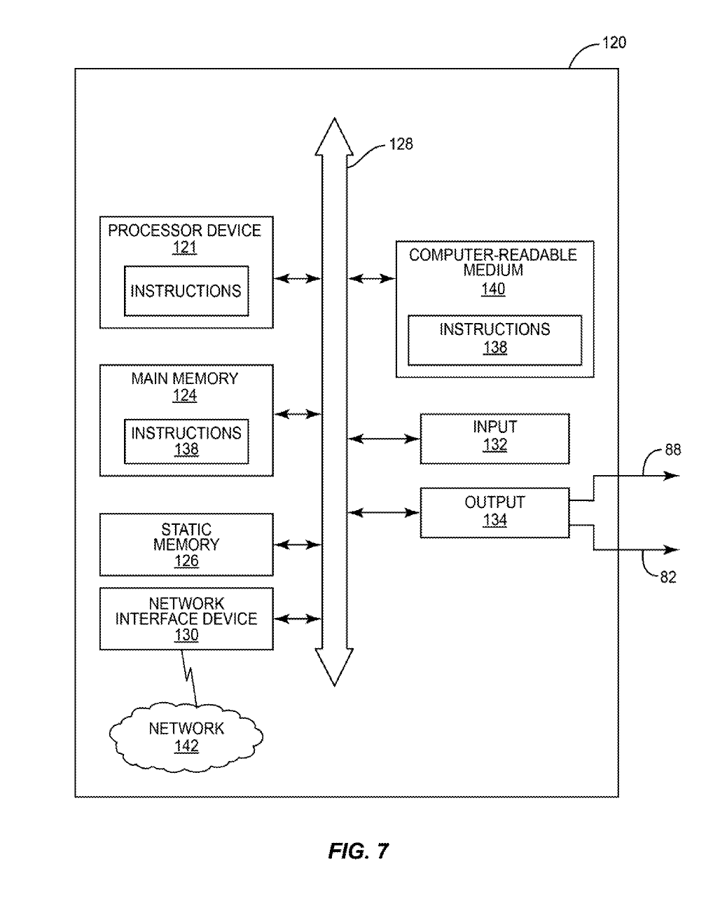

FIG. 7 is a schematic diagram representation of additional detail illustrating a computer system 120 that could be employed in the electrical test probe 72 in FIG. 5 to execute instructions from an exemplary computer-readable medium to control disposing of the conductive coupling posts 44(1), 44(2) of the electrical-test substrates 40, 40′ into contact with the interconnect bumps 46(1), 46(2) of the IC 42 to electrically test the IC 42. In this regard, the computer system 120 in FIG. 7 may include a set of instructions that may be executed to generate the test signal 88 and the rotation signal 82 to control the test press 83 and the rotation of the unwind reel 74 and the wind reel 76, as previously discussed above with regard to FIG. 5. The computer system 120 may be connected (e.g., networked) to other machines in a local area network (LAN), an intranet, an extranet, or the Internet. While only a single device is illustrated, the term “device” shall also be taken to include any collection of devices that individually or jointly execute a set (or multiple sets) of instructions to perform any one or more of the methodologies discussed herein. The computer system 120 may be a circuit or circuits included in an electronic board card, such as, a printed circuit board (PCB), a server, a personal computer, a desktop computer, a laptop computer, a personal digital assistant (PDA), a computing pad, a mobile device, or any other device, and may represent, for example, a server or a user's computer.

The exemplary computer system 120 in this aspect includes a processing device or processor 122, a main memory 124 (e.g., read-only memory (ROM), flash memory, dynamic random access memory (DRAM), such as synchronous DRAM (SDRAM), etc.), and a static memory 126 (e.g., flash memory, static random access memory (SRAM), etc.), which may communicate with each other via a data bus 128. Alternatively, the processor 122 may be connected to the main memory 124 and/or static memory 126 directly or via some other connectivity means. The processor 122 may be the controller 84 of FIG. 5, and the main memory 124 or static memory 126 may be any type of memory.

The processor 122 represents one or more general-purpose processing devices, such as a microprocessor, central processing unit (CPU), or the like. More particularly, the processor 122 may be a complex instruction set computing (CISC) microprocessor, a reduced instruction set computing (RISC) microprocessor, a very long instruction word (VLIW) microprocessor, a processor implementing other instruction sets, or other processors implementing a combination of instruction sets. The processor 122 is configured to execute processing logic in instructions for performing the operations and steps discussed herein.

The computer system 120 may further include a network interface device 130. The computer system 120 also may or may not include an input 132, configured to receive input and selections to be communicated to the computer system 120 when executing instructions. The computer system 120 also may or may not include an output 134, including but not limited to a display, a video display unit (e.g., a liquid crystal display (LCD) or a cathode ray tube (CRT)), an alphanumeric input device (e.g., a keyboard), and/or a cursor control device (e.g., a mouse). The output 134 can include the test signal 88 and the rotation signal 82 to control the test press 83 and the rotation of the unwind reel 74 and the wind reel 76, as previously discussed above with regard to FIG. 5.

The computer system 120 may or may not include a data storage device 136 that includes instructions 138 stored in a computer-readable medium 140. The instructions 138 may also reside, completely or at least partially, within the main memory 124 and/or within the processor 122 during execution thereof by the computer system 120, the main memory 124 and the processor 122 also constituting the computer-readable medium 140. The instructions 138 may further be transmitted or received over a network 142 via the network interface device 130.

While the computer-readable medium 140 is shown in an exemplary aspect to be a single medium, the term “computer-readable medium” should be taken to include a single medium or multiple media (e.g., a centralized or distributed database, and/or associated caches and servers) that store the instructions 138. The term “computer-readable medium” shall also be taken to include any medium that is capable of storing, encoding, or carrying a set of instructions for execution by the processing device and that cause the processing device to perform any one or more of the methodologies of the aspects disclosed herein. The term “computer-readable medium” shall accordingly be taken to include, but not be limited to, solid-state memories, optical medium, and magnetic medium.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. An electrical-test substrate for providing electrical contact to bumps in an integrated circuit (IC) during electrical testing of the IC, comprising:
a backside structure comprising a flexible dielectric film structure;
at least one conductive pad formed over a front side of the flexible dielectric film structure;
at least one opening formed over the at least one conductive pad at a first pitch; and
at least one conductive coupling post positioned within the at least one opening to provide a second pitch of the at least one conductive coupling post at substantially the first pitch, the at least one conductive coupling post configured for coupling with at least one bump of an IC during electrical testing of the IC.

2. The electrical-test substrate of claim 1, wherein the backside structure is comprised entirely of the flexible dielectric film structure.

3. The electrical-test substrate of claim 1, further comprising at least one conductive end pad disposed on the backside structure of the at least one conductive end pad coupled with the at least one conductive coupling post configured to allow an electrical coupling to the at least one conductive coupling post by an electrical test apparatus.

4. The electrical-test substrate of claim 1, further comprising a solder resist material disposed above the front side of the backside structure, wherein the at least one opening is further disposed in the solder resist material.

5. The electrical-test substrate of claim 1, comprised of a single layer of the at least one conductive coupling post.

6. The electrical-test substrate of claim 1, wherein the at least one conductive coupling post is configured to be brought into contact with the at least one bump of the IC.

7. The electrical-test substrate of claim 1, wherein the first pitch is approximately forty (40) micrometers (μm) or less to provide the second pitch of the at least one conductive coupling post of approximately forty (40) micrometers (μm) or less.

8. The electrical-test substrate of claim 1, wherein the first pitch is approximately thirty (30) micrometers (μm) or less to provide the second pitch of the at least one conductive coupling post of approximately thirty (30) micrometers (μm) or less.

9. The electrical-test substrate of claim 1, wherein the first pitch is approximately twenty (20) micrometers (μm) or less to provide the second pitch of the at least one conductive coupling post of approximately twenty (20) micrometers (μm) or less.

10. The electrical-test substrate of claim 1, wherein:
the at least one conductive pad is comprised of a plurality of conductive pads formed over the front side of the flexible dielectric film structure;
the at least one opening is comprised of a plurality of openings each formed over a conductive pad among the plurality of conductive pads at the first pitch; and
the at least one conductive coupling post is comprised of a plurality of conductive coupling posts each positioned within an opening among the plurality of openings to provide the second pitch of the plurality of conductive coupling posts at substantially the first pitch, the plurality of conductive coupling posts configured for coupling with the at least one bump of the IC during the electrical testing of the IC.

11. The electrical-test substrate of claim 1, wherein the IC is comprised of a semiconductor die.

12. The electrical-test substrate of claim 11, wherein the semiconductor die is comprised of a 2.5D IC die.

13. The electrical-test substrate of claim 12, wherein the semiconductor die is comprised of a 3DIC die.

14. The electrical-test substrate of claim 1, wherein the IC is comprised of an interposer.

15. The electrical-test substrate of claim 1, wherein the flexible dielectric film structure comprises a polymer.

16. The electrical-test substrate of claim 15, wherein the polymer comprises polyimide.

17. The electrical-test substrate of claim 1, wherein the at least one conductive coupling post is comprised of at least one plated copper post.

18. A method of fabricating an electrical-test substrate comprising a plurality of conductive coupling posts configured for coupling at least one bump in an integrated circuit (IC) during electrical testing of the IC, comprising:
providing a backside structure comprised of a flexible dielectric film structure having a back side and a front side;
forming a conductive layer overlying the front side of the flexible dielectric film structure;
forming a first at least one opening in the conductive layer to provide remaining portions of the conductive layer;
forming a solder resist layer in the first at least one opening to form a second at least one opening of a first depth and having a first pitch, over the remaining portions of the conductive layer; and
forming at least one conductive coupling post in the second at least one opening to provide a second pitch of the at least one conductive coupling post at substantially the first pitch.

19. The method of claim 18, wherein providing the backside structure further comprises providing the backside structure comprised entirely of the flexible dielectric film structure.

20. The method of claim 18, further comprising:
forming a first photoresist layer overlying the conductive layer;
exposing the first photoresist layer to form the first at least one opening;
removing portions of the conductive layer disposed below the first at least one opening in the first photoresist layer to providing the remaining portions of the conductive layer; and
removing remaining portions of the first photoresist layer.

21. The method of claim 20, wherein:
forming the solder resist layer comprises forming the solder resist layer in the first at least one opening in the first photoresist layer to form the second at least one opening of a first depth having the first pitch of forty (40) micrometers (μm) or less in the first photoresist layer over the remaining portions of the conductive layer; and
further comprising:
providing a second photoresist layer over the solder resist layer to increase the first depth of the second at least one opening to a second depth; and
removing the second photoresist layer to expose the at least one conductive coupling post from the solder resist layer.

22. The method of claim 18, wherein forming the at least one conductive coupling post further comprises plating the second at least one opening.

23. The method of claim 18, wherein forming the solder resist layer further comprises forming the solder resist layer in the first at least one opening at the first pitch of approximately forty (40) micrometers (μm) or less.

24. The electrical-test substrate of claim 1, wherein the at least one conductive coupling post is configured to be brought into mechanical contact with the at least one bump of the IC during the electrical testing of the IC.

25. An electrical test probe for electrical testing of an integrated circuit (IC), comprising:
an unwind reel configured to be rotated in a first direction in response to a rotation signal;
a wind reel configured to be rotated in the first direction in response to the rotation signal;
a tape comprising a plurality of electrical-test substrates disposed end-to-end from a first end of the tape to a second end of the tape, the first end of the tape wound around the unwind reel and the second end of the tape wound around the wind reel;
each of the plurality of electrical-test substrates comprising:
a backside structure comprising a flexible dielectric film structure;
at least one conductive pad formed over a front side of the flexible dielectric film structure;
at least one opening formed over the at least one conductive pad at a first pitch; and
at least one conductive coupling post positioned within the at least one opening to provide a second pitch of the at least one conductive coupling post at substantially the first pitch of the at least one opening, the at least one conductive coupling post configured for coupling with at least one bump of an IC during electrical testing of the IC;
a test press disposed between the unwind reel and the wind reel, the test press configured to be disposed downward in response to a test signal to come into contact with the backside structure of an electrical-test substrate among the plurality of electrical-test substrates unwound from the unwind reel and disposed below the test press to press the at least one conductive coupling post in the electrical-test substrate to couple with the at least one bump in the IC disposed underneath the test press; and
a controller configured to:
generate the rotation signal to cause the unwind reel and the wind reel to rotate in the first direction to dispose an unwound electrical-test substrate among the plurality of electrical-test substrates below the test press; and
generate the test signal to cause the test press to be disposed downward to come into contact with the backside structure of the electrical-test substrate among the plurality of electrical-test substrates unwound from the unwind reel to press the at least one conductive coupling post in the electrical-test substrate to couple with the at least one bump in the IC disposed underneath the test press.

26. The electrical test probe of claim 25, wherein the controller is further configured to generate the test signal to control a distance that the test press is disposed downward to couple with the backside structure of the electrical-test substrate.
